(19) United States
(12) Patent Application Publication
(10) Pub. No.: US 2014/0244190 A1
(43) Pub. Date: Aug. 28, 2014

(54) POWER USAGE ANALYSIS

(71) Applicant: CELLCO PARTNERSHIP D/B/A VERIZON WIRELESS, Basking Ridge, NJ (US)

(72) Inventor: Paul BERMAN, Roselle Park, NJ (US)

(73) Assignee: CELLCO PARTNERSHIP D/B/A VERIZON WIRELESS, Basking Ridge, NJ (US)

(21) Appl. No.: 13/780,361

(22) Filed: Feb. 28, 2013

(51) Int. Cl. G01R 21/00

(52) U.S. Cl. CPC G01R 21/00
USPC 702/61

(57) ABSTRACT

A user device is configured to receive information that a display screen, of the user device, is turned on; and receive information that an application is initiated or used on the user device during a time period that commences based on the display screen being turned on. The user device is configured to determine an amount of power used by the display screen; determine power usage information that identifies a portion of the amount of power that is attributable to the application based on the application being initiated during the time period; and store the power usage information.

### BACKGROUND

A user device (e.g., a smart phone) may be used for a variety of different reasons. For example, the user device may be used to send/receive text messages, browse the Internet, play games, communicate with other user devices, and/or other functions.

### BRIEF DESCRIPTION OF DRAWINGS

FIG. 1 is a diagram of an overview of an implementation described herein;

FIG. 2 is a diagram of an example environment in which systems and/or methods described herein may be implemented;

FIG. 3 is a diagram of example components of one or more devices of FIG. 1 and FIG. 2;

FIG. 4 is a flow chart of an example process for determining power usage;

FIG. 5 is a diagram of an example data structure; and

FIGS. 6A-6C are diagrams of an example process for determining power usage.

### DETAILED DESCRIPTION OF PREFERRED EMBODIMENTS

The following detailed description refers to the accompanying drawings. The same reference numbers in different drawings may identify the same or similar elements.

A user of a user device may be provided with information regarding the power usage of the user device. A user device may provide information to the user that the user device is using a particular amount of power for a particular application. For example, the user device may provide the user with information that 20% of the power is being used for an email application. The information may also inform the user of the amount of power being used to power the display screen of the user device. However, the information may not inform the user why the display screen was turned on and how much of the power, being used by the display screen, is attributable to different applications executing on the user device. Systems and/or methods described herein may determine what percentage of the power, used to power the display screen, is being used by a particular application executing on the user device.

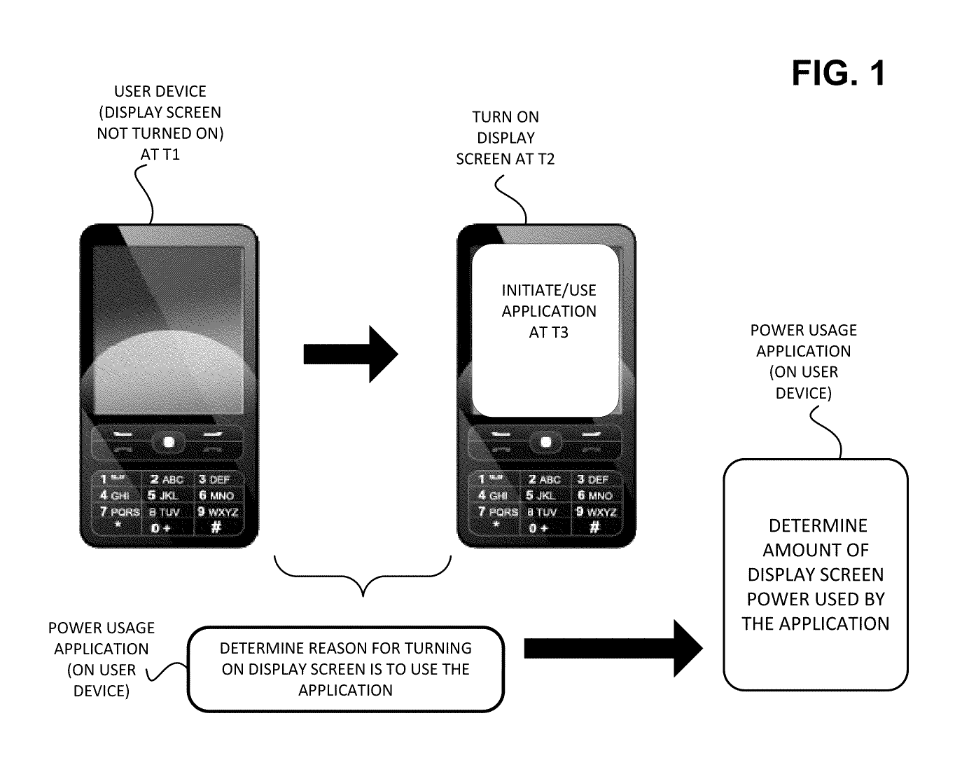

FIG. 1 is a diagram of an overview of an implementation described herein. As shown in FIG. 1, a display screen, of a user device, is not turned on at time T1. At time T2, which occurs after time T1, the display screen is turned on by a user of the user device. At time T3, which occurs after time T2, a particular application (stored by the user device) is initiated and/or used by a user of the user device.

The user device may have a power usage application. The power usage application may receive information regarding whether an application is initiated and/or used during a time period commencing after the display screen is turned on. Assume that the time T3 occurs within the time period. The power usage application may determine that the reason for turning on the display screen is to use the particular application. Further, the power usage application may determine that part of the power being used to power the display screen can be attributed to activation of the display for use by the particular application. The above described determinations made by the power usage application, also known as power usage information, may be stored by the power usage application and/or provided in a report to the user.

The power usage information may be sent by the power usage application to a power usage server (not shown in FIG. 1) associated with a service provider. The power usage server may use the screen power usage information to analyze how different applications on a user device affect the power usage of the user device.

As a result, a user may be able to determine how much power being used by the display screen is associated with different tasks performed by the user using the user device. This may assist the user in determining which tasks use up more power associated with the display screen than other tasks. Additionally, or alternatively, a service provider may use the information to assist the service provider in troubleshooting issues relating to power usage by a customer's user device.

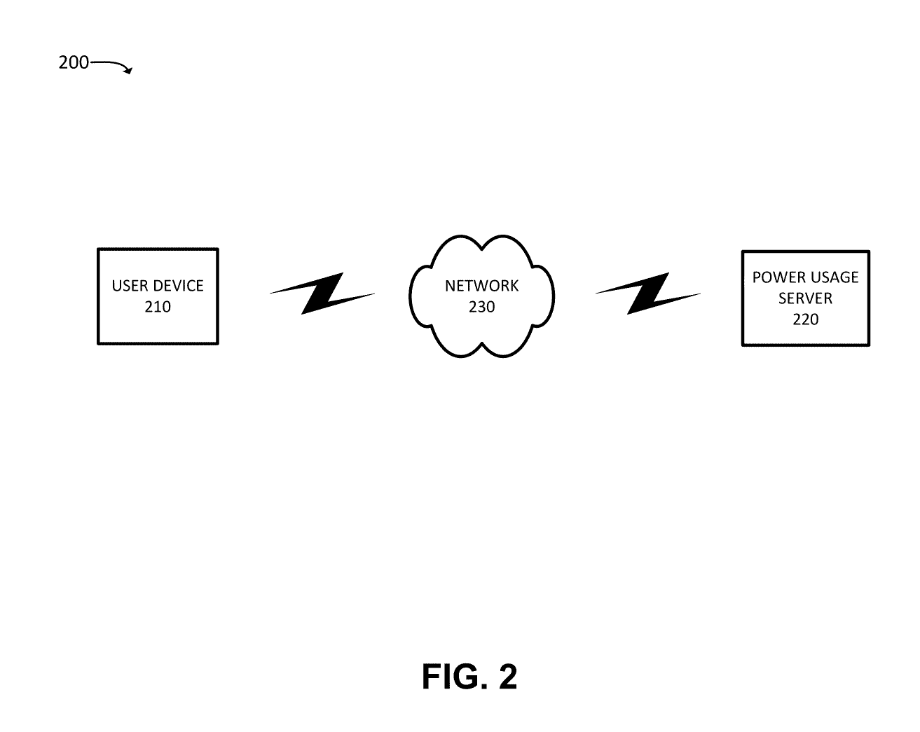

FIG. 2 is a diagram of an example environment 200 in which systems and/or methods described herein may be implemented. As shown in FIG. 2, environment 200 may include a user device 210, a power usage server 220, and a network 230.

User device 210 may include any mobile computation or communication device that is capable of sending content and/or information via network 230 to other user devices 210 and/or other types of devices, such as power usage server 220. For example, user device 210 may include a smart phone, cellular phone, a camera, a gaming device, or any other mobile computation or communication device.

User device 210 may include a power usage application that determines how much of the display screen power is associated with different applications being used on user device 210. In some implementations, the power usage application may be a standalone application executing on user device 210. In some other implementations, the power usage application may be part of another application executing on user device 210 (e.g., a function of the other application), such as part of an application that monitors or controls power consumption on user device 210. In some example implementations, the power usage application may automatically run in the background on user device 210. In some other example implementations, the power usage application may run only when initiated by a user of user device 210.

Power usage server 220 may include one or more server devices that are capable of receiving and analyzing power usage information from user device 210. In some implementations, power usage server 220 may be associated with a service provider that provides a service (e.g., a communication service, a network service, etc.) to user device 210. In some implementations, power usage server 220 may communicate with a group of user devices to receive and analyze power usage information for the group of user devices 210.

Network 230 may include a cellular network, a public land mobile network (PLMN), a second generation (2G) network, a third generation (3G) network, a fourth generation (4G) network, a fifth generation (5G) network, and/or another network. Additionally, or alternatively, network 230 may include a local area network (LAN), a wide area network (WAN), a metropolitan network (MAN), a telephone network (e.g., the Public Switched Telephone Network (PSTN)), an ad hoc network, an intranet, the Internet, a satellite network, a global positioning system (“GPS”) network, a fiber optic-based network, and/or a combination of these or other types of networks. Additionally, or alternatively, network 230 may support secure communications via a private network (e.g., a virtual private network (VPN) or a private IP VPN (PIP VPN), and/or secure communications via a public network.

The quantity of devices and/or networks, illustrated in FIG. 2 is provided for explanatory purposes only. In practice, there may be additional devices and/or networks; fewer devices and/or networks; different devices and/or networks; or differently arranged devices and/or networks than illustrated in FIG. 2. Also, in some implementations, one or more of the devices of environment 200 may perform one or more functions described as being performed by another one or more of the devices of environment 200. Devices of environment 200 may interconnect via wired connections, wireless connections, or a combination of wired and wireless connections.

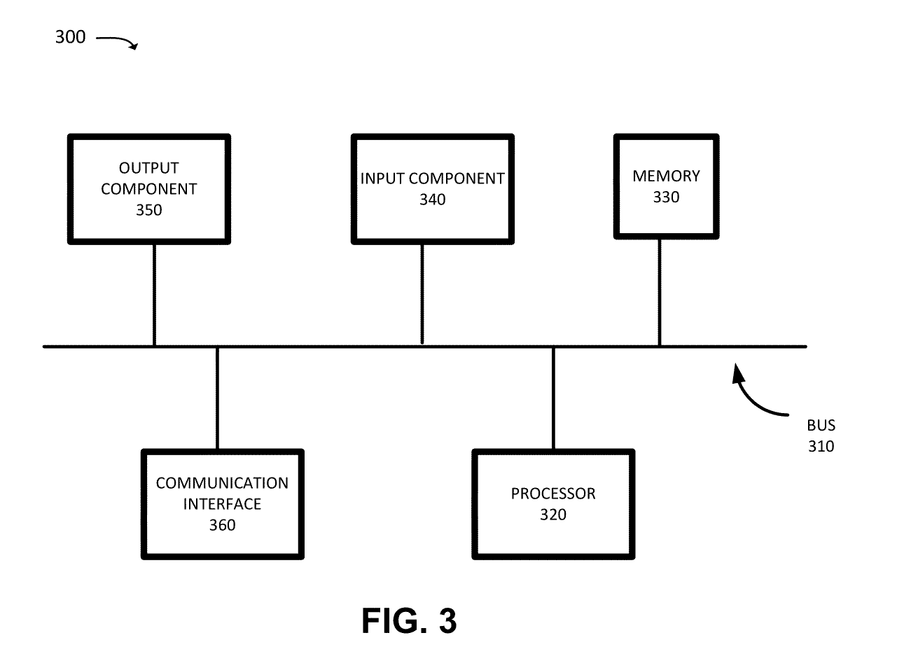

FIG. 3 is a diagram of example components of a device 300. Device 300 may correspond to user device 210 and/or power usage server 220. Additionally, or alternatively, each of user device 210 and/or power usage server 220 may include one or more devices 300 and/or one or more components of device 300.

As shown in FIG. 3, device 300 may include a bus 310, a processor 320, a memory 330, an input component 340, an output component 350, and a communication interface 360.

Bus 310 may include a path that permits communication among the components of device 300. Processor 320 may include one or more processors, microprocessors, or processing logic (e.g., a field programmable gate array (FPGA), or an application specific integrated circuit (ASIC)) that interprets and executes instructions. Memory 330 may include any type of dynamic storage device that stores information and instructions, for execution by processor 320, and/or any type of non-volatile storage device that stores information for use by processor 320.

Input component 340 may include a component that permits a user to input information to device 300, such as a keyboard, a keypad, a button, a switch, etc. Output component 350 may include a component that outputs information to the user, such as a display, a speaker, one or more light emitting diodes (LEDs), etc.

Communication interface 360 may include any transceiver-like mechanism that enables device 300 to communicate with other devices and/or systems. For example, communication interface 360 may include an Ethernet interface, an optical interface, a coaxial interface, a wireless interface, or the like.

In another implementation, communication interface 360 may include, for example, a transmitter that may convert baseband signals from processor 320 to radio frequency (RF) signals and/or a receiver that may convert RF signals to baseband signals. Alternatively, communication interface 360 may include a transceiver to perform functions of both a transmitter and a receiver of wireless communications (e.g., radio frequency, infrared, visual optics, etc.), wired communications (e.g., conductive wire, twisted pair cable, coaxial cable, transmission line, fiber optic cable, waveguide, etc.), or a combination of wireless and wired communications.

Communication interface 360 may connect to an antenna assembly (not shown in FIG. 3) for transmission and/or reception of the RF signals. The antenna assembly may include one or more antennas to transmit and/or receive RF signals over the air. The antenna assembly may, for example, receive RF signals from communication interface 360 and transmit the RF signals over the air, and receive RF signals over the air and provide the RF signals to communication interface 360. In one implementation, for example, communication interface 360 may communicate with other networks and/or devices connected to network 230.

As will be described in detail below, device 300 may perform certain operations. Device 300 may perform these operations in response to processor 320 executing software instructions (e.g., computer program(s)) contained in a computer-readable medium, such as memory 330, a secondary storage device (e.g., hard disk, CD-ROM, etc.), or other forms of RAM or ROM. A computer-readable medium may be defined as a non-transitory memory device. A memory device may include space within a single physical storage device or spread across multiple physical storage devices. The software instructions may be read into memory 330 from another computer-readable medium or from another device. The software instructions contained in memory 330 may cause processor 320 to perform processes described herein. Alternatively, hardwired circuitry may be used in place of or in combination with software instructions to implement processes described herein. Thus, implementations described herein are not limited to any specific combination of hardware circuitry and software.

While FIG. 3 shows device 300 as having a particular quantity and arrangement of components, in other implementations, device 300 may contain fewer components, additional components, different components, or differently arranged components than depicted in FIG. 3. Additionally, or alternatively, one or more components of device 300 may perform one or more tasks described as being performed by one or more other components of device 300.

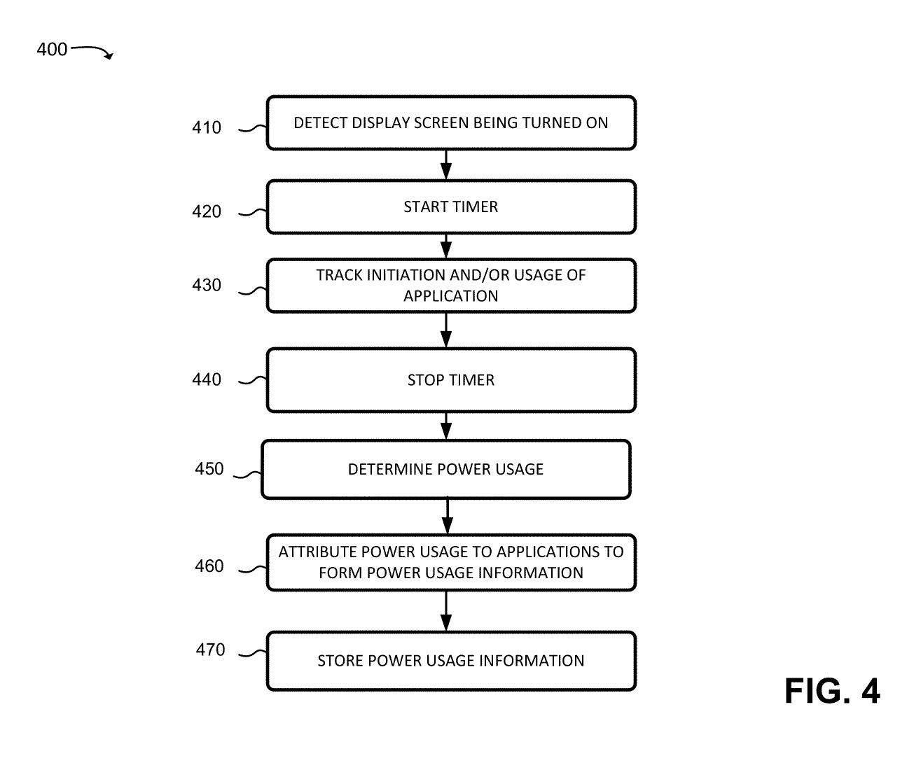

FIG. 4 is a flow chart of an example process 400 for determining power usage. In one example implementation, one or more blocks of process 400 may be performed by user device 210.

Process 400 may include detecting a display screen being turned on (block 410). For example, a user of user device 210 may turn on a display screen of user device 210. A power usage application, executing on user device 210, may detect that the display screen of user device 210 is turned on. The display screen may be turned on in response to user device 210 being activated from a power-off mode or a sleep mode.

In some implementations, the power usage application may be downloaded (via network 230) onto user device 210 upon the initial setup of user device 210 when user device 210 is first used by the user. In some implementations, the power usage application may be pre-installed within the memory of user device 210. In some implementations, the user (of user device 210) may select the power usage application and download the power usage application onto user device 210.

The user may be given the option to send the power usage information to power usage server 220. For example, the power usage application may request the user's permission to have power usage information sent to power usage server 220. The user may configure the power usage application to have power usage information sent to power usage server 220 after a particular amount of time (e.g., every 24 hours, once a week, once a month, etc.). The user may configure the power usage application to generate a report (displayed on user device 210, power usage server 220, or some other device associated with the user or the service provider) after a particular amount of time (e.g., every 12 hours, every 24 hours, etc.). The user may configure the power usage application to send the report to a device associated with the user or the service provider in a particular manner, such as via an email, a pop-up window, an audible message, and/or another type of communication. The user may use the power usage application to configure the type of information in the report and/or the type of information sent to power usage server 220. For example, the user may configure the format of the report (e.g., display power usage information in terms of percentages).

The power usage application may be configured to execute each time that the display screen of user device 210 is turned on. Alternatively, the power usage application may execute based on the user's configuration of the power usage application (e.g., execute during a particular time of the day). Alternatively, the power usage application may execute based on receiving an instruction from power usage server 220. For example, power usage server 220 may instruct the power usage application to only execute during weekday hours.

Process 400 may include starting a timer (block 420). For example, the power usage application may start a timer based on the display screen of user device 210 being turned on. In some implementations, the timer may be configured to count to a particular value (to reflect a particular time period) and stop counting. In some implementations, the timer may take another form to identify a start or end of the particular time period.

The power usage application may determine the start or end of the time period based on one or more factors. One factor could relate to an amount of time associated with the user entering in a password (e.g., a numerical code, a pattern-based touch screen code, voice pattern recognition code, etc.) to unlock user device 210 once the display screen is turned on. Another factor could relate to an amount of time associated with the user starting a task on user device 210. For example, initiating an application may take two seconds (e.g., to find and activate the application). Another factor could relate to an amount of time associated with using the application. For example, generating and sending a text message may take six seconds, or, for example, generating and sending a request to receive video content onto user device 210 may take four seconds. Thus, the time period may take into consideration the amount of time to turn on the display screen, unlock user device 210, initiate an application on user device 210, and/or use the application.

In some implementations, the power usage application may be preconfigured by the provider (e.g., the service provider or a third party) of the power usage application with the start or end of time period based on past usage information of multiple user devices 210. For example, the provider may receive information, relating to one or more of the factors identified above, from multiple user devices 210 and determine the start or end of the time period based on this information.

In some implementations, the power usage application may have a preconfigured time period and the power usage application may update the start or end of the time period based on the user's interactions with user device 210. In this case, the power usage application (or another application executing on user device 210 or power usage server 220) may collect information regarding how long it takes for certain activities to be performed on user device 210, such as how long it takes the user to unlock user device 210, how long it takes the user to initiate an application after unlocking user device 210, how long it takes the user to initiate and use an application after unlocking user device 210, etc. The power usage application may use the collected information directly, or periodically (e.g., daily, monthly, every 10 times that the display screen is turned on, every 50 times that the display screen is turned on, etc.) calculate averages or moving averages, to determine whether to update the start or end of the time period. For example, the time period may be increased if the user, over time, takes a greater amount of time to unlock user device 210, if the user, over time, takes a greater amount of time to initiate an application, and/or if any other user interaction indicates that it would be beneficial to increase the time period. Alternatively, the power usage application may decrease the time period if the user, over time, takes a lesser amount of time to unlock user device 210, if the user, over time, takes a lesser amount of time to initiate an application, and/or if any other user interaction indicates that it would be beneficial to decrease the time period.

Process 400 may include tracking an initiation and/or usage of an application (block 430). For example, the power usage application may track an initiation and/or usage of an application executing on user device 210 while the display screen is turned on. The power usage application may track the initiation and/or usage of the application during the time period that begins when the power usage application starts the timer (as described above).

The power usage application may track the initiation of an application during the time period. For example, during the time period, assume that the user, of user device 210, starts a text message application. The power usage application may store information that indicates that the user initiated the text message application during the time period. In some implementations, the power usage application may store the information when the user initiated the text message application during the time period regardless of whether the user subsequently interacted with the text message application. In some implementations, the power usage application may store the information when the user initiated the text message application during the time period and kept the text message application active on the display screen until the end of the time period regardless of whether the user subsequently interacted with the text message application.

Additionally, or alternatively, the power usage application may only track a threshold number of applications that are initiated during the time period. If the number of applications initiated is greater than the threshold, then the power usage application may determine which applications were the first threshold-number of applications, or the last (most recent) threshold-number of applications, initiated before the end of the time period. For example, assume that the user initiates, within the time period, six applications and the threshold is five applications. In this case, the power usage application may only consider the first (or last) five applications for determining power usage even though the user initiated a sixth application during the time period. In some implementations, the power usage application may be preconfigured to use the first threshold-number of applications or the last threshold-number of applications. In some other implementations, the power usage application may determine whether to use the first threshold-number of applications or the last threshold-number of applications based on one or more factors, such as a factor relating to application usage (e.g., trends, patterns, etc.) on user device 210, a factor relating to application usage (e.g., trends, patterns, etc.) by users of multiple user devices 210 (which may be obtained from power usage server 220), or the like.

Additionally, or alternatively, the power usage application may track and store information regarding the first application initiated by the user after the display screen is turned on. For example, the user may initiate four different applications within the time period, the first application being a gaming application. The power usage application may only consider the gaming application for determining power usage as the gaming application is the first application initiated by the user.

Additionally, or alternatively, the power usage application may track the initiation and the usage of the application. For example, assume that the user, of user device 210, initiates a music application and uses the music application to listen to music content during the time period. The power usage application may store information that indicates that the user initiated the music application and used the music application during the time period. In some implementations, the power usage application may store the information only when the user both initiated the music application and used the music application during the time period. In other words, if the user only initiated the music application or only used the music application, the power usage application would not store the information.

In some implementations, the power usage application may store the information only when the user both initiated the music application and used the music application for a particular amount of time greater than a threshold within the time period. For example, if the user used the music application for five seconds within a 10 second time period and the threshold is three seconds, then the power usage application may store the information. The threshold may be different for different types of applications (e.g., three seconds for a weather application, five seconds for a text message application, etc.).

Additionally, or alternatively, the power usage application may track the usage of the application. For example, the user may have, prior to turning on the display screen of user device 210, used the application and then turned off the display screen. Upon turning on the display screen, the application may still be active.

For example, at 1:00 p.m., a user may have been using an email application on user device 210. At 1:05 p.m., the user may stop using user device 210 and user device 210 may go into sleep mode which results in the display screen turning off. At 1:30 p.m., the user may turn the display screen of user device 210 back on when user device 210 is awakened from its sleep mode. Assume that turning on the display screen begins the time period. At 1:30 p.m., the email application may still be active on the user device. Assume that the user uses the email application to send an email during the time period. The power usage application may store information that indicates that the user used the email application during the time period. In some implementations, the power usage application may store the information when the user used the email application during the time period regardless of whether the user also initiated the email application during the time period.

Process 400 may include stopping the timer (block 440). For example, the power usage application may stop the timer at the end of the time period. At the end of the time period, the power usage application may determine why the display screen was turned on and how much power, being used by the display screen, is attributable to one or more applications initiated and/or used by user device 210.

Process 400 may include determining power usage (block 450). For example, the power usage application may determine the amount of power used by the display screen of user device 210. For example, the power usage application may determine that the display screen is using 30% of the total amount of power used by user device's 210.

Since the display screen of user device 210 may be turned on a number of times (e.g., three times a day, six times a day, 20 times a day, etc.), in some implementations, the power usage application may determine the amount of power usage based upon an aggregate number of times (e.g., after user device 210 has been turned on 10 times, 20 times, 30 times, etc.) that the display screen is turned on. In some implementations, the power usage application may determine the amount of power usage after a period of time (e.g., every 12 hours, every day, every two days, etc.), regardless of the number of times that the display screen is turned on.

Process 400 may include attributing the power usage to applications to form power usage information (block 460). For example, the power usage application may determine how much of the power being used to power the display screen is attributable to different applications that have been initiated and/or used during the time period.

For example, assume that the display screen, of user device 210, is turned on five times within 24 hours. During the first two times, assume that the user only uses a text message application during the time period. During the third time, assume that the user only uses user device 210 to check the weather using a weather application during the time period. During the fourth and fifth times, assume that the user uses a music application on user device 210. In this example, the power usage application may determine that within a 24 hour period, that 40% of the power usage by the display screen may be attributed to the text message application, 40% of the power usage by the display screen may be attributed to the music application, and 20% of the power usage by the display screen may be attributed to the weather application. The power usage application may store a data structure that can be used to determine how much of the screen power is being attributed to different applications initiated and/or used on user device 210.

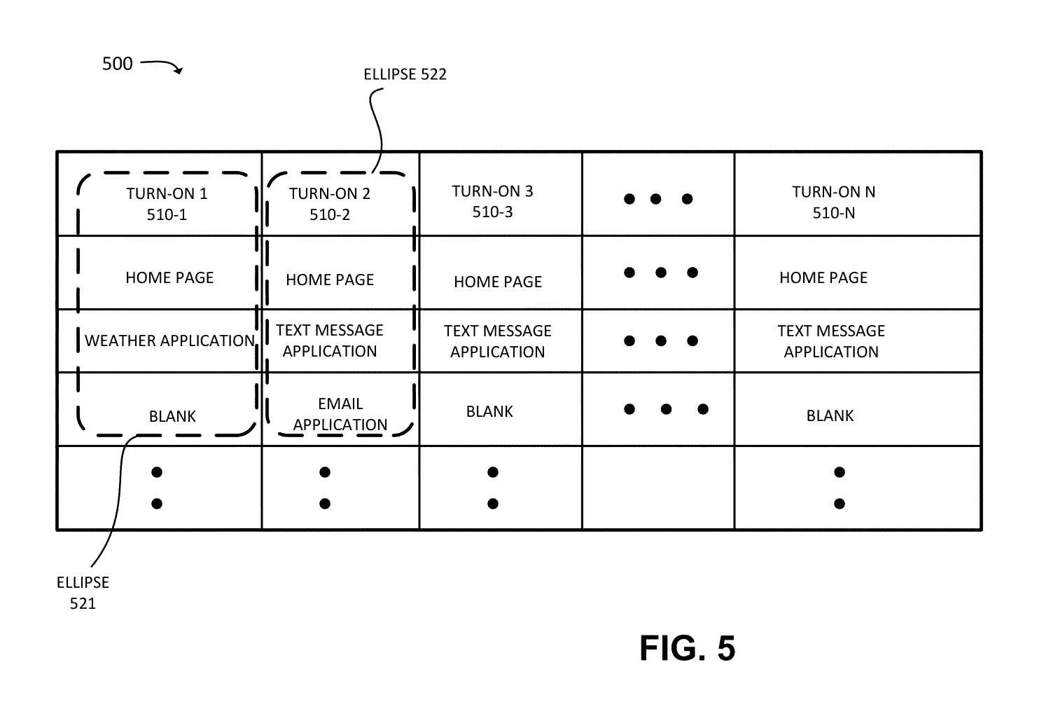

Process 400 may include storing the power usage information (block 470). For example, the power usage application may store the power usage information in a data structure. One example of such a data structure will be described with regard to FIG. 5.

The power usage application may use the power usage information and provide (via the display screen of user device 210) the user with information regarding how much of the power, used by the display screen, is attributable to different applications initiated and/or used on user device 210. For example, the user may be provided with information that user device 210 is being turned on a particular number of times (e.g., five times, eight times, 12 times, etc.) during a period of time (e.g., over 12 hours, one day, two days, etc.). For example, the information may indicate that user device 210 was turned on six times within 24 hours to send text messages.

Additionally, or alternatively, the power usage application may use the power usage information to provide the user with suggestions for increasing battery usage. For example, if the power usage information indicates that most of the power, used by the display screen, is attributable to a music application, the power usage application may provide the user with a suggestion to dim the display screen by a particular amount to increase the battery life.

Additionally, or alternatively, the power usage application may provide information to the user regarding how much of the power, used by the display screen, is attributable to different applications initiated and/or used on user device 210. For example, the information may indicate 30% of the power used by the user device 210's display screen is attributable to an email application initiated and/or used on user device 210.

Additionally, or alternatively, the power usage application may send the power usage information to power usage server 220. Power usage server 220 may receive the power usage information from the power usage application. An operator may retrieve (e.g., via a workstation or a computing device) the information from power usage server 220. The operator may be an employee of a service provider that provides service to user device 210. The operator may use power usage information from multiple user devices 210 to determine (e.g., using power usage server 220 or another device) how different third party applications affect the power consumption by the display screens of user devices 210. This may permit the service provider to determine that a particular third party application is using excessive user device 210 power resources which may not comply with an agreement between the service provider and the third party application provider.

Further, the service provider may use the power usage information to provide the user with suggestions for increasing battery usage. For example, if the power usage information indicates that most of the power, used by the display screen of a user device 210, is attributable to a voice application, the service provider may provide the user with a suggestion to dim the display screen by a particular amount to increase the battery life.

Further, the service provider may use power usage information from multiple user devices 210 to determine whether a particular type of user device 210 has issues with the user device 210's battery or whether a particular application is causing power usage issues on the multiple user devices 210.

While a series of blocks has been described with regard to FIG. 4, the order of the blocks may be modified in other implementations. Further, non-dependent blocks may be performed in parallel. Other changes to the blocks may also be possible.

For example, while process 400 has been described as being performed by user device 210, one or more blocks of process 400 may be performed by one or more other devices, such as power usage server 220. In this case, the power usage application may be configured to transmit information to power usage server 220, such as information indicating that the display screen has been turned on, which application(s) have been initiated and/or used, and/or how much power has been used by the display screen. Power usage server 220 may use this information to attribute the power usage, by the display screen, to the application(s) that have been initiated and/or used on user device 210.

FIG. 5 is an example data structure 500 that may be used to store power usage information. In some implementations, user device 210 may store some or all of data structure 500. In some implementations, power usage server 220 may store some or all of data structure 500. In some implementations, data structure 500 may be stored in memory, associated with another device or a group of devices, separate from, or in combination with memory associated with user device 210 and/or power usage server 220.

Data structure 500 may include a collection of fields, such as turn-on 1 field 510-1, turn-on 2 field 510-2, turn-on 3 field 510-3, . . . , turn-on N field 510-N (N≧1) (referred to generally as “turn-on fields 510” and individually as “turn-on field 510”).

Turn-on field 510 may store information that uniquely identifies applications that are initiated and/or used by a user of user device 210 during the time period determined by the power usage application.

For example, ellipse 521 may store information identifying the applications initiated and/or used during a time period that occurs after a display screen of user device 210 is turned on (turn-on 1). For example, assume that the time period is 11 seconds. During the time period, as shown in ellipse 521, the user initiates the home page, initiates a weather application and keeps the weather application active on the display screen but does not use the weather application.

Similarly, ellipse 522 may store information identifying the applications initiated and/or used during the time period that occurs after the display screen user device 210 is turned on again (turn-on 2). For example, assume that the time period is 11 seconds. During the time period, as shown in ellipse 522, the user initiates the home page, initiates and uses a text message application, and initiates an email application.

The power usage application may use the information in data structure 500 to infer why the display screen of user device 210 was turned on. Further, the power usage application may determine how much of the power allocated to the display screen is associated with applications being initiated and/or used on user device 210.

While FIG. 5 shows example field 510, in some implementations, data structure 500 may include fewer fields, different fields, additional fields, and/or differently arranged fields than depicted in FIG. 5.

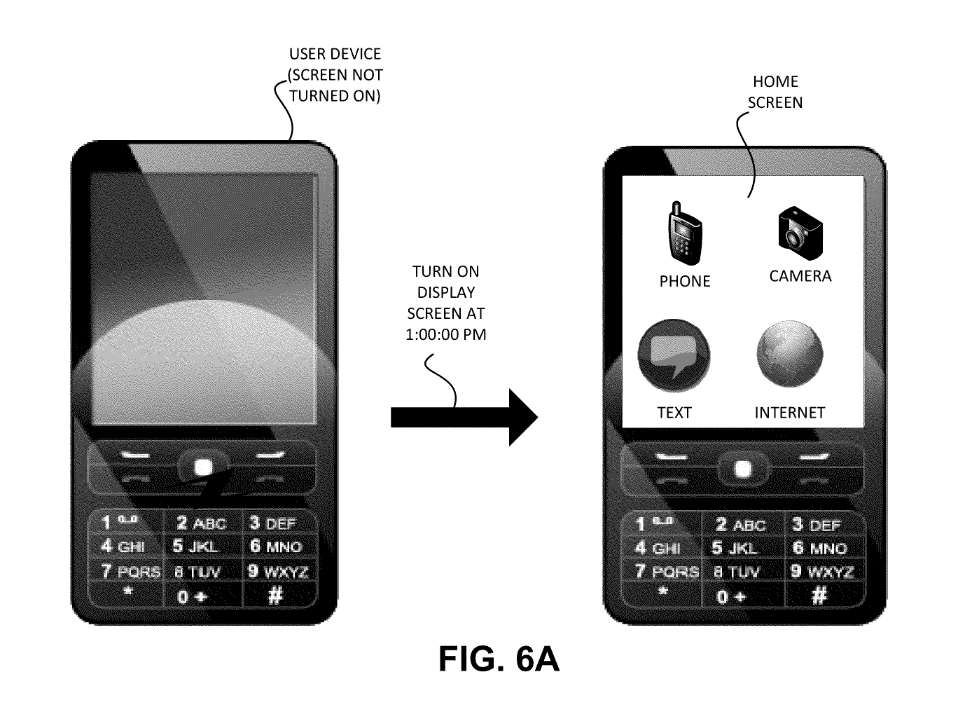

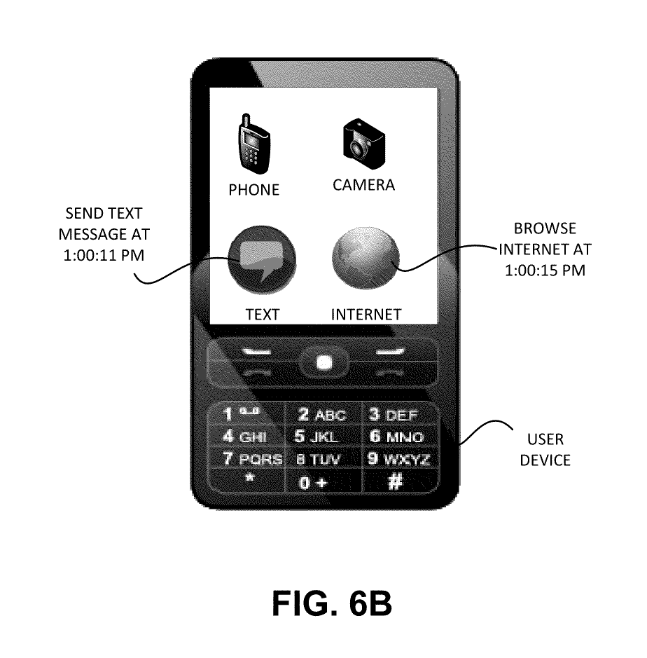

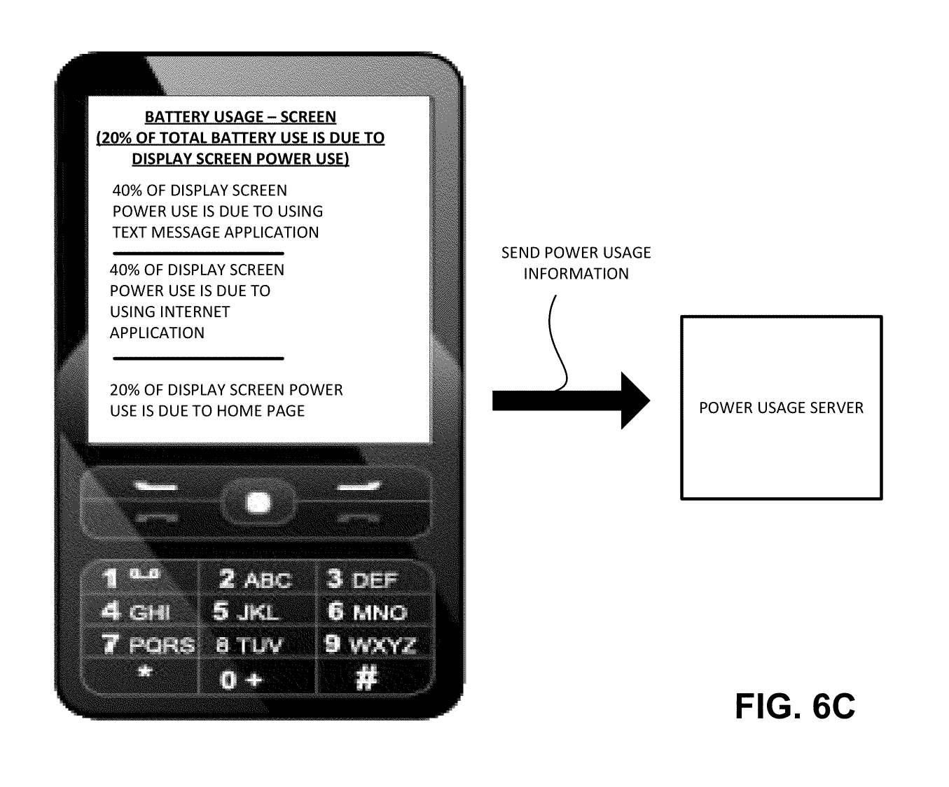

FIGS. 6A-6C are diagrams of example processes for determining power usage. As shown in FIG. 6A, assume that a display screen of user device is not turned on. Assume that the user device is in sleep mode. A user may decide to awake the user device at 1:00:00 p.m. Upon awakening the user device, the display screen may turn on and a home screen may be displayed to the user. As shown in FIG. 6A, the home screen may display icons that represent different applications that can be used on the user device. This includes a phone application, a camera application, a text message application (shown as “text”), and an Internet application (shown as “Internet”).

Assume that the user device has a power usage application. Assume that the power usage application has been configured to identify applications on the user device during a time period that starts from when the user device is turned on. Assume that the time period is 30 seconds.

As shown in FIG. 6B, the user may send a text message at 1:00:11 p.m. and at 1:00:15 p.m. may browse the Internet. At 1:00:30 p.m., the power usage application may determine that the reason why the display screen was turned on at 1:00:00 p.m. was for the user to initiate and use the text message application and the Internet application.

Assume that the user does not turn on the display screen again during the day. Assume that the following day, the user turns on the display screen and receives a message, as shown in FIG. 6C, generated by the power usage application. As shown in FIG. 6C, the message may display to the user (based on a determination made by the power usage application) that 20% of the user device's battery is due to the display screen. Further, the message may display to the user that 40% of the display screen power is based on the user sending text messages, 40% of the display screen power is based on the user using the Internet application, and 20% of the display screen power is used by the home screen application.

The power usage information may also be sent to a power usage server. The power usage server may receive the power usage information. The power usage server may use the screen power usage information to analyze how different applications on a user device affect the power usage of the user device.

As a result, a user may be able to determine how much power being used by the display screen is associated with different tasks performed by the user using the user device. This may assist the user in determining which tasks use up more power associated with the display screen than other tasks. Additionally, or alternatively, a service provider may use the information to assist the service provider in troubleshooting issues relating to power usage by a customer's user device.

The foregoing description of implementations provides illustration and description, but is not intended to be exhaustive or to limit the implementations to the precise form disclosed. Modifications and variations are possible in light of the above disclosure or may be acquired from practice of the implementations.

It will be apparent that example aspects, as described above, may be implemented in many different forms of software, firmware, and hardware in the implementations illustrated in the figures. The actual software code or specialized control hardware used to implement these aspects should not be construed as limiting. Thus, the operation and behavior of the aspects were described without reference to the specific software code—it being understood that software and control hardware could be designed to implement the aspects based on the description herein.

Even though particular combinations of features are recited in the claims and/or disclosed in the specification, these combinations are not intended to limit the disclosure of the possible implementations. In fact, many of these features may be combined in ways not specifically recited in the claims and/or disclosed in the specification. Although each dependent claim listed below may directly depend on only one other claim, the disclosure of the possible implementations includes each dependent claim in combination with every other claim in the claim set.

No element, act, or instruction used in the present application should be construed as critical or essential unless explicitly described as such. Also, as used herein, the article “a” is intended to include one or more items and may be used interchangeably with “one or more.” Where only one item is intended, the term “one” or similar language is used. Further, the phrase “based on” is intended to mean “based, at least in part, on” unless explicitly stated otherwise.

What is claimed is:

1. A method comprising:
receiving, by a user device, information that a display screen of the user device is turned on;
receiving, by the user device, information that an application is initiated on the user device during a time period that commences based on the display screen being turned on;
determining, by the user device, an amount of power used by the display screen;
determining, by the user device, power usage information that identifies a portion of the amount of power that is attributable to the application based on the application being initiated during the time period; and
storing, by the user device, the power usage information.

2. The method of claim 1, further comprising:
determining the time period based on an amount of time associated with unlocking the user device, an amount of time associated with initiating an application, or an amount of time associated with using the application.

3. The method of claim 1, further comprising:
sending the power usage information to a server, the server using the power usage information to resolve an issue
regarding power usage by the user device.

4. The method of claim 1, where the application is a first application,
the method further comprising:
receiving information that a second application is initiated and used on the user device during the time period;
determining second power usage information that identifies a second portion of the amount of power that is attributable to the second application based on the second application being initiated and used during the time period; and
storing the second power usage information.

5. The method of claim 4, further comprising:
generating a message for display on the display screen,
the message including information regarding the power usage information and the second power usage information.

6. The method of claim 4, further comprising:
sending the power usage information and the second power usage information to a server,
the server using the power usage information and the second power usage information to resolve an issue regarding power usage by the user device.

7. The method of claim 1, where the application is a first application,
the method further comprising:
receiving information that a second application is initiated and used on the user device for a particular amount of time during the time period;
determining that the particular amount of time is greater than a threshold;
determining a second power usage information that identifies a second portion of the amount of power that is attributable to the second application based on the second application being initiated and used on the user device for the particular amount of time during the time period and based on the particular amount of time being greater than the threshold; and
storing the second power usage information.

8. The method of claim 1, where the application is a first application,
the method further comprising:
receiving information that a second application is initiated and used on the user device for a particular amount of time during the time period;
determining that the particular amount of time is less than a threshold; and
determining that the amount of power is not attributable to the second application based on the particular amount of time being less than the threshold.

9. A computer-readable medium comprising:
a plurality of instructions that, when executed by one or more processors of a user device, cause the one or more processors to:
receive information that a display screen of the user device is turned on;
receive information that an application is initiated or used on the user device during a time period that commences based on the display screen being turned on;
determine an amount of power used by the display screen;
determine power usage information that identifies a portion of the amount of power that is attributable to the application based on the application being initiated or used during the time period; and
store the power usage information.

10. The computer-readable medium of claim 9, where:
the plurality of instructions, when executed by the one or more processors, further cause the one or more processors to:
send the power usage information to a server,
the server using the power usage information to resolve an issue regarding power usage by the user device.

11. The computer-readable medium of claim 9, where the application is a first application,
the plurality of instructions, when executed by the one or more processors, further causing the one or more processors to:
receive information that a second application is initiated and used on the user device during the time period;
determine second power usage information that identifies a second portion of the amount of power that is attributable to the second application based on the second application being initiated and used during the time period; and
store the second power usage information.

12. The computer-readable medium of claim 9, where the application is a first application,
the plurality of instructions, when executed by the one or more processors, further causing the one or more processors to:
receive information that a second application is being used on the user device for a particular amount of time during the time period;
determine that the particular amount of time is greater than a threshold;
determine a second power usage information that identifies a second portion of the amount of power that is attributable to the second application based on the second application being used on the user device for the particular amount of time during the time period and based on the particular amount of time being greater than the threshold; and
store the second power usage information.

13. The computer-readable medium of claim 9, where the application is a first application,
the plurality of instructions, when executed by the one or more processors, further causing the one or more processors to: <receive information that a second application is being used on the user device during the time period;
determine second power usage information that identifies a second portion of the amount of power that is attributable to the second application and based on the second application being used on the user device during the time period; and
store the second power usage information.

14. The computer-readable medium of claim 9, where one or more instructions, of the plurality of instructions, to receive information that an application is initiated or used on the user device include one or more instructions to:
receive information that the application is an initial application initiated on the user device after the display screen is turned on; and
where one or more instructions, of the plurality of instructions, to determine power usage information that identifies the portion of the amount of power that is attributable to the application include one or more instructions to:
determine that the portion of the amount of power that is attributable to the application is based on the application being the initial application.

15. A device comprising:
a processor to:
receive information that a display screen, associated with the device, is turned on;
receive information that an application is initiated or used on the device during a time period that commences based on the display screen being turned on;
determine an amount of power used by the display screen;
determine power usage information that identifies a portion of the amount of power that is attributable to the application based on the application being initiated or used on the device during the time period; and
store the power usage information.

16. The device of claim 15, the processor is further to:
send the power usage information to a server,
the server using the power usage information to resolve an issue regarding power usage by the device.

17. The device of claim 15, the processor is further to:
determine the time period based on a first amount of time associated with unlocking the device and a second amount of time associated with initiating an application.

18. The device of claim 15, the processor is further to:
generate a message for display on the display screen,
the message including information regarding the power usage information.

19. The device of claim 15, the processor is further to:
adjust the time period based on use of the device.

20. The device of claim 15, where the application is the first application,
the processor being further to:
receive information that a second application is being used on the device for a particular amount of time during the time period;
determine that the particular amount of time is greater than a threshold;
determine second power usage information that identifies a second portion of the amount of power that is attributable to the second application based on the second application being used on the device for the particular amount of time during the time period and based on the particular amount of time being greater than the threshold; and
store the second power usage information.
